(19) United States
(12) Patent Application Publication
(10) Pub. No.: US 2021/0366798 A1
(43) Pub. Date: Nov. 25, 2021

(54) PACKAGED STRUCTURE AND FORMING METHOD THEREOF

(71) Applicant: Changxin Memory Technologies, Inc., Hefei (CN)

(72) Inventor: Chih-Wei CHANG, HEFEI (CN)

(21) Appl. No.: 17/396,691

(22) Filed: Aug. 7, 2021

Related U.S. Application Data
(63) Continuation of application No. PCT/CN2020/130381, filed on Nov. 20, 2020.

(30) Foreign Application Priority Data
Mar. 13, 2020 (CN) 202010174461.6

(51) Int. Cl. H01L 23/13; H01L 23/00; H01L 21/56

(52) U.S. Cl. CPC H01L 23/13; H01L 24/73; H01L 21/563; H01L 23/3128; H01L 24/92; H01L 2224/92125; H01L 2224/73204; H01L 24/32

(57) ABSTRACT

A packaged structure and a forming method thereof are provided. The packaged structure includes: a substrate having a first surface and a second surface opposite to each other, the first surface including at least one strip-shaped groove having two ends extending to edges of the substrate and open to the exterior, with a depth less than the thickness of the substrate; a chip fastened onto the first surface in a flipping manner and electrically connected to the substrate, and at least partially located within the projection of the chip on the substrate; a bottom filling layer filling the gap between the chip and the first surface; and a plastic packaging layer covering the bottom filling layer and packaging the chip. The packaged structure effectively removes the gas inside the packaged structure in the injection molding process without affecting the connection area on the back surface of the substrate.

### CROSS-REFERENCE TO RELATED APPLICATIONS

This application is a continuation application of International Patent Application No.: PCT/CN2020/130381, filed on Nov. 20, 2020, which claims priority to Chinese Patent Application No. 202010174461.6, filed on Mar. 13, 2020. The above-referenced applications are incorporated herein by reference in their entirety.

### TECHNICAL FIELD

The present invention relates to the field of chip packaging, and in particular, to a packaged structure and a forming method thereof.

### BACKGROUND

After a chip is packaged, it needs to be packaged through an injection molding process to protect the chip.

A chip packaged in a flipping manner (i.e., a “flip-chip”) is connected to a circuit on a substrate using solder balls. In an injection molding process, the chip needs to be packaged by a plastic packaging material to fill the gap between the chip and the substrate. Because the chip is directly connected to the substrate through the solder balls or other solder bumps, the gap between the chip and the substrate is relatively small, so is the spacing between connection points. During the injection molding process, air may trapped when the gap is filled with the plastic packaging material. As such, air bubbles may form in the plastic packaging material between the chip and the substrate as the plastic packaging material cures, thereby affecting the stability of the flip-chip. For example, air bubbles trapped in the plastic packaging material can expand/contract due to thermal expansion, potentially causing the flip-chip to separate from the substrate over time.

In existing techniques, to facilitate the gas removal in the injection molding process, a plurality of air holes may be formed in the packaged substrate, so that gas may be removed through the air holes in the substrate during the filling of plastic packaging material in the injection molding process.

FIG. 1 is a schematic top view of a substrate 100 having air holes 101 in existing techniques. A plurality of air holes may be formed in the substrate to improve the gas removal efficiency. Since most of the area on the substrate is used to connect to a chip, the area that can be used to form the air holes is relatively small. When a large number of air holes are formed, the size of each of the air holes is relatively small. Although the number of gas removal positions can be increased by increasing the number of air holes, the improvement to the gas removal efficiency is limited because the air holes are small and are prone to be blocked by the plastic packaging material. Additionally, since the air holes penetrate through the substrate and occupy the area used to form a circuit in the substrate, they hindered the circuit design in the substrate. Particularly, the number and distribution position of the solder balls formed on the back surface of the substrate may be greatly affected by the air holes, resulting in a reduced connection region on the back surface of the substrate.

Therefore, there is an urgent need for a package structure and a forming method thereof to eliminate residual gas in the packaged structure without adversely affecting the connection region on the back surface of the substrate of a packaged chip in the injection molding process.

### SUMMARY

The technical problem to be resolved in the present invention is to provide a packaged structure and a forming method thereof to improve the reliability of the packaged structure without adversely affecting the connection region on the back surface of a substrate.

One aspect of the present invention is directed to a packaged structure. The packaged structure may include a substrate, a chip, a bottom filling layer, and a plastic packaging layer.

The substrate may have a first surface and a second surface opposite to each other. The first surface may include at least one strip-shaped groove having two ends extending to the edges of the substrate and open to the exterior. The depth of the groove may be smaller than the thickness of the substrate.

The chip may be fastened onto the first surface of the substrate in a flipping manner by using solder bumps and may be electrically connected to the substrate through the solder bumps. At least a portion of the groove may be located within the projection of the chip on the substrate when viewed along a direction perpendicular to the first surface.

The bottom filling layer may fill the gap between the chip and the first surface of the substrate. The plastic packaging layer may cover the bottom filling layer and package the chip.

In some embodiments, the first surface of the substrate may include at least two grooves arranged parallelly or crossly.

In some embodiments, the width of the groove may be smaller than the fillable width of the material of the bottom filling layer in the liquid state.

In some embodiments, the width of the groove may be smaller than 4 μm.

In some embodiments, the depth of the groove may be in the range of 1% to 70% of the thickness of the substrate.

In some embodiments, the depth of the groove may be 80 μm to 0.5 mm.

In some embodiments, the groove may be straight or curved.

In some embodiments, the at least one groove may be located at the position of a symmetry axis of the substrate.

In some embodiments, when viewed along a direction perpendicular to the first surface, the substrate may have a rectangular shape having a long side and a short side, and the at least one groove may extend along the long side of the substrate.

In some embodiments, the top of the groove may be sealed by the bottom filling layer, and the groove may have a continuous gas path formed inside the groove.

In some embodiments, the packaged structure may further include solder balls, formed on the second surface of the substrate.

Another aspect of the present invention is directed to a forming method of a packaged structure. The method may include providing a packaged chip and performing injection molding on the packaged chip.

The packaged chip may include a substrate and a chip fastened onto the substrate. The substrate may have a first surface and a second surface opposite to each other. The first surface may include at least one strip-shaped groove having two ends extending to edges of the substrate and open to the exterior. The depth of the groove may be smaller than the thickness of the substrate.

The chip may be fastened onto the first surface of the substrate in a flipping manner by using solder bumps. The solder bumps may be electrically connected to the substrate. At least a portion of the groove may be located within the projection of the chip on the substrate when viewed along a direction perpendicular to the first surface.

The injection molding may be performed on the packaged chip to form a bottom filling layer filling the gap between the chip and the first surface of the substrate, a plastic packaging layer covering the bottom filling layer and packaging the chip.

In some embodiments, the gas inside the packaged structure may be removed through the groove in the process of forming the bottom filling layer.

In some embodiments, performing injection molding on the packaged chip may include: providing an injection mold, the injection mold including an under-pan and a cover configured to cover the under-pan to form a cavity with the under-pan; placing the packaged chip in the cavity, the substrate being placed on the surface of the under-pan; filling, using the capillary effect, a bottom filler in the gap between the bottom of the chip and the substrate; injecting a liquid-state plastic packaging material into the cavity until the cavity is filled with the liquid-state plastic packaging material; and performing heating to solidify the liquid-state plastic packaging material and the bottom filler, to form the solid-state plastic packaging layer and bottom filling layer.

In some embodiments, the cover may include at least one hole connecting the cavity to outside. And the method may further include injecting the liquid-state plastic packaging material into the cavity through the at least one hole.

In some embodiments, the cover may include at least two holes. And the method may further include removing the gas inside the cavity through at least one of the holes in the injection molding process.

In some embodiments, in the injection molding process, the bottom filler may seal the top of the groove, without filling the groove, to form a continuous gas path inside the groove.

In some embodiments, the method may further include forming solder balls on the second surface of the substrate.

According to the packaged structure provided in the present invention, the groove having two ends open to the exterior may be formed in the first surface of the substrate to remove gas in the process of forming the bottom filling layer. In addition, the depth of the groove may be smaller than the depth of the substrate, so that the distribution of metal wires and solder balls on the second surface of the substrate is not affected, thereby improving the utilization rate of the second surface of the substrate.

Further, the width of the groove may be smaller than the fillable width of the bottom filling layer, so that the bottom filler only partially fills the groove in the injection molding process, thereby preventing the groove from being blocked and improving the gas removal efficiency of the groove.

### BRIEF DESCRIPTION OF DRAWINGS

FIG. 1 is a schematic top view of a substrate having a plurality of air holes.

FIGS. 2A, 2B and 2C are schematic structural views of the substrate of a packaged structure according to an embodiment of the present invention.

FIGS. 3A and 3B are schematic views of the substrate of a packaged structure according to an embodiment of the present invention.

FIG. 4 is a schematic structural view of the substrate of a packaged structure according to an embodiment of the present invention.

FIG. 5 is a schematic structural view of the substrate of a packaged structure according to an embodiment of the present invention.

FIG. 6 is a schematic structural view of the substrate of a packaged structure according to an embodiment of the present invention.

FIG. 7 is a schematic flowchart of a method for forming a packaged structure according to an embodiment of the present invention.

### DESCRIPTION OF EMBODIMENTS

The accompanying drawings, which are incorporated in and constitute a part of the specification, illustrate embodiments of the present invention and, together with the specification, explain the principles of the present invention. It is apparent that the drawings in the following description are only some of the embodiments of the present invention, and other drawings may be obtained from those skilled in the art without departing from the drawings. The dimensions in the accompanying drawings are illustrative and may not represent the actual scale.

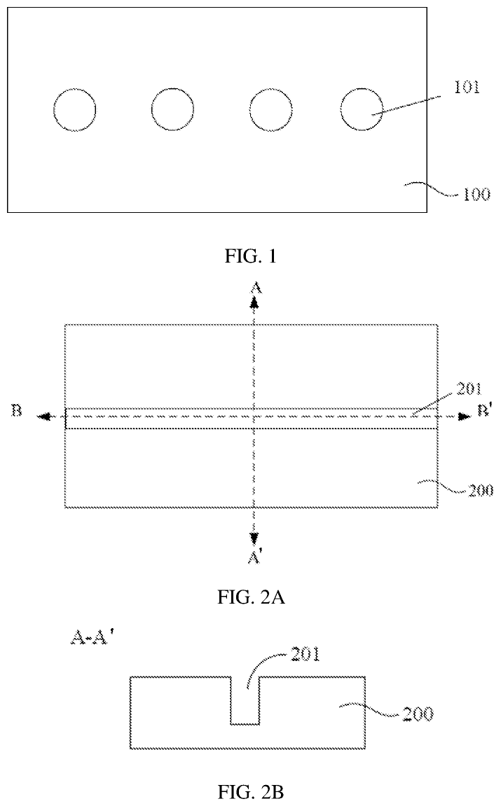

FIGS. 2A, 2B, and 2C are schematic structural views of the substrate of a packaged structure according to an embodiment of the present invention. FIG. 2A is a schematic top view of the substrate, FIG. 2B is a schematic cross-sectional view of the substrate along the direction of A-A′ in FIG. 2A, and FIG. 2C is a schematic cross-sectional view of the substrate along the direction of B-B′ in FIG. 2A. The package structure is described below in detail with reference to these drawings.

Referring to FIG. 2A, the package structure may include a substrate 200. The substrate 200 may have a first surface and a second surface opposite to each other. The first surface may have a chip fastened thereon, and the second surface may have solder balls formed thereon to connect to another circuit board.

The substrate 200 may be a circuit board. Electrical connection structures such as an interconnection circuit and a solder pad (not shown in the drawings) may be formed on the surface of the substrate 200 and/or inside the substrate 200 to electrically connect to the chip to input an electrical signal into the chip or to output an electrical signal generated by the chip.

The first surface of the substrate 200 may include one strip-shaped groove 201 having two ends extending to the edges of the substrate 200 and open to the exterior. The depth of the groove 201 may be smaller than the thickness of the substrate, as shown in FIG. 2B.

In some embodiments, the groove 201 may be a long straight groove of uniform width. The bottom of the groove 201 may be located inside the substrate 200. The groove 201 may serve as a path for removing gas inside the packaged structure in the injection molding process of the packaged chip. The gas may be removed from the two ends of the groove 201 at the edges of the substrate 200 and open to the exterior.

To prevent an injection molding material from entering into the groove 201 in the injection molding process to block the groove 201 and adversely affect the gas removal, the width of the groove 201 may be smaller than the fillable width of the injection molding material in the liquid state. When the width of the groove 201 is smaller than the fillable width, the liquid-state injection molding material cannot be filled in the groove 201 under the action of surface tension due to the relatively high viscosity of the injection molding material. Specifically, the width of the groove 201 may be smaller than 4 μm, and may be, for example, 2 μm or 3 μm, 1 μm. A person skilled in the art can reasonably set the width of the groove 201 under the condition that the width of the groove 201 is smaller than the fillable width, so that the groove 201 may have better gas removal efficiency while preventing the injection molding material from entering the groove 201.

The area of a cross-section of the groove 201 in the direction perpendicular to the length may determine the gas removal efficiency. When the width of the groove 201 is limited, the depth of the groove 201 may be set to adjust the gas removal efficiency of the groove 201.

The depth of the groove 201 may be smaller than the depth of the substrate 200 to maintain the integrity of the second surface of the substrate 200, so that the distribution of structures such as solder bumps and solder balls on the second surface of the substrate 200 may not be affected. The depth of the groove 201 may not be too large to prevent the strength of the substrate 200 from being adversely affected and causing problems such as breakage. In some embodiments, the depth of the groove 201 may be in the range of 1% to 70% of the thickness of the substrate 200. In some embodiments, the depth of the groove 201 may be in the range of 80 μm to 0.5 mm.

In some embodiments, when viewed along a direction perpendicular to the first surface of the substrate 200, the substrate 200 may have a rectangular shape having a long side and a short side, and the groove 201 may extend along the long side of the substrate 200. Since gas is more difficult to be removed in the injection molding process along the long side of the substrate, disposing the groove 201 along the long side of the substrate 200 may improve the gas removal efficiency. In some other embodiments, when the substrate has a rectangular shape having a long side and a short side, there may be at least one groove extending along the long side of the substrate.

In some embodiments, the groove 201 may be disposed on a symmetry axis of the substrate 200, thereby improving the structural symmetry of the substrate 200, the symmetry of internal stress distribution in the substrate 200, and the stability of the packaged structure.

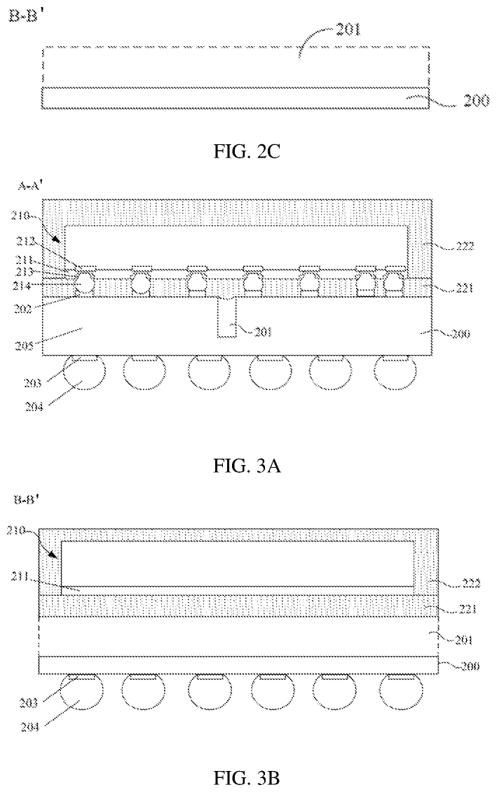

FIGS. 3A and 3B are schematic cross-sectional views of the packaged structure along the direction of A-A′ and B-B′ of the substrate in FIG. 2A, respectively, according to an embodiment of the present invention.

Referring to FIGS. 3A and 3B, the packaged structure may further include a chip 210, a bottom filling layer 221 filling the gap between the chip 210 and the substrate 200, and a plastic packaging layer 222 covering the bottom filling layer 221 and packaging the chip 210.

In some embodiments, the bottom filling layer 221 may fill between the chip 210 and the substrate 200 and may further cover the substrate 200 outside the chip 210. The plastic packaging layer 222 may cover the surface of the bottom filling layer 221. In some other embodiments, the edges of the substrate 200 may not be covered by the bottom filling layer 221, but instead be directly covered by the plastic packaging layer 222. And the plastic packaging layer 222 may cover a portion of the surface and side walls of the bottom filling layer 221. In some other embodiments, the bottom filling layer 221 may be located only under the chip 210, and the plastic packaging layer 222 may cover the side walls of the bottom filling layer 221.

The chip 210 may be fastened onto the first surface of the substrate 200 in a flipping manner by using solder bumps and may be electrically connected to the substrate 200 through the solder bumps. When viewed along a direction perpendicular to the first surface, at least a portion of the groove 201 may be located within the projection of the chip 210 on the substrate 200.

The surface of the chip 210 may have a passivation layer 211 covering the solder pads 212 of the chip 210. The solder bump may include a lower bump metal layer 213 located in the passivation layer 211 and formed on the surface of the solder pad 212, and a solder ball 214 formed on the surface of the lower bump metal layer 213. In some other embodiments, the solder bump may further include structures such as a metal rod. The solder ball 214 may be connected to a circuit inside the chip 210 through the solder pad 212.

The first surface of the substrate 200 may include a connection structure 202, such as a solder pad or a metal wire. The chip 210 may be fastened to the connection structure 202 by soldering through the solder ball 214 to implement an electrical connection. The second surface of the substrate 200 may include a connection structure 203 and a solder ball 204 formed on the connection structure 203. The solder ball 204 may be configured to weld the packaged structure onto another circuit board. The substrate 200 may further include an interconnection structure 205 such as a connection rod penetrating through the substrate 200, configured to form an electrical connection between the connection structure 202 on the first surface and the connection structure 203 on the second surface of the substrate 200.

The circuit connection mode in the substrate 200 may be designed according to a specific chip, which is not limited herein.

Because the width of the groove 201 is smaller than the fillable width of the material of the bottom filling layer 211 in the liquid state, the bottom filling layer 221 of the packaged structure may seal only the opening on the top of the groove 201 without filling the groove 201, and a continuous gas path may be formed inside the groove 201. Thus, the groove 201 may effectively remove gas when forming the bottom filling layer 211 through injection molding.

Because the bottom of the groove 201 is located inside the substrate 200, the distribution and the area of the connection region on the second surface of the substrate 200 may not be adversely affected, and the entire second surface of the substrate 200 may be used as a connection region for connecting to another circuit board and for forming the solder balls 204. The solder balls 204 may be distributed more flexibly and the substrate 200 may have more flexible internal circuit wiring. For example, a larger spacing between the solder balls 204 may be set, thereby reducing the soldering difficulty in the subsequent mounting of the packaged structure onto other circuit boards.

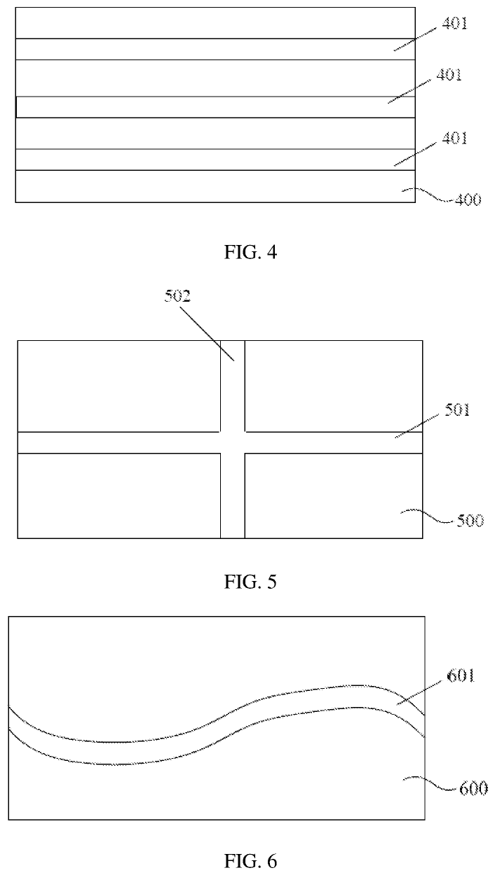

FIG. 4 is a schematic top view of a substrate 400 used in a packaged structure according to another embodiment of the present invention.

Referring to FIG. 4, the substrate 400 may have three strip-shaped grooves 401 arranged parallelly formed on the surface of the substrate 400. All the three grooves 401 may have a shape of a long rectangle and may be evenly distributed in the substrate 400. Additionally, one of the grooves 401 may be disposed at the position of a symmetry axis of the substrate 400.

Excessively large spacing between the adjacent grooves 401 may reduce the gas removal efficiency, resulting in the gas not being removed in time, and excessively small spacing between the adjacent grooves 401 can cause uneven internal stress distribution of the substrate 400, thereby adversely affecting the strength of the substrate 400. Preferably, the spacing between the adjacent grooves 401 may be in the range of 50 μm to 5 mm, so as to achieve a relatively good gas removal efficiency while keeping the sufficient strength of the substrate 400. A person skilled in the art can reasonably set the spacing between the adjacent grooves 401 based on factors such as the actual thickness and size of the substrate while achieving a relatively good gas removal efficiency.

In some embodiments, the substrate of the packaged structure may include two or more grooves to improve the gas removal efficiency during injection molding. The grooves may be arranged parallelly or crossly and have different depths and widths. The groove may have a cross-section having a shape of a rectangular, a circle or an oval when viewed along the direction perpendicular to the length. The cross-section of the groove may have other shapes, and this specification is not limited in this regard.

FIG. 5 is a schematic top view of the substrate 500 used in a packaged structure according to yet another embodiment of the present invention.

Referring to FIG. 5, the substrate 500 may include a groove 501 and a groove 502. When viewed along the top surface of the substrate 500, the substrate 500 may have a shape of a rectangle having a long side and a short side. The groove 501 may be disposed along the long side of the substrate 500, and the groove 502 may be disposed along the short side of the substrate 500. The groove 501 and the groove 502 may be disposed at the positions of two symmetry axes of the substrate 500, respectively. The groove 501 and the groove 502 may be connected vertically.

FIG. 6 is a schematic structural view of the substrate of a packaged structure according to yet another embodiment of the present invention.

Referring to FIG. 6, the substrate 600 may have a groove 601. The groove 601 may have a curved shape. The curved shape of the groove 601 may increase the length of the groove 601, so that the groove may occupy more area under a chip, thereby facilitating the removal of the gas.

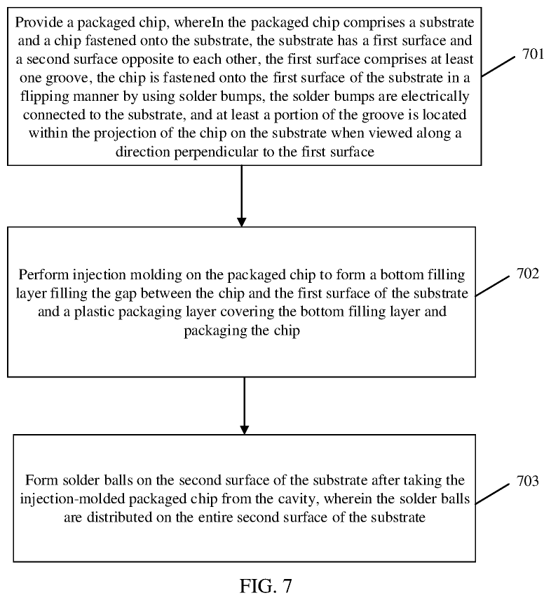

This specification further presents a method for forming the foregoing packaged structure. FIG. 7 is a schematic flowchart of a method for forming a packaged structure according to an embodiment of the present invention. Referring to FIG. 7, the method may include the following steps 701 through 703.

In step 701, a packaged chip may be provided. The packaged chip may include a substrate and a chip fastened onto the substrate. The substrate may have a first surface and a second surface opposite to each other. The first surface may include at least one groove. The chip may be fastened onto the first surface of the substrate in a flipping manner by using solder bumps. The solder bumps may be electrically connected to the substrate. At least a portion of the groove may be located within the projection of the chip on the substrate when viewed along a direction perpendicular to the first surface.

In some embodiments, the groove may be strip-shaped and may have two ends extending to the edges of the substrate and open to the exterior. The depth of the groove may be smaller than the thickness of the substrate.

In some embodiments, the first surface of the substrate may include at least two grooves arranged parallelly or crossly.

In some embodiments, the width of the groove may be smaller than 4 μm.

In some embodiments, the depth of the groove may be in the range of 1% to 70% of the thickness of the substrate.

In some embodiments, the depth of the groove may be 80 μm to 0.5 mm.

In some embodiments, the groove may be straight or curved.

In some embodiments, the at least one groove may be located at the position of a symmetry axis of the substrate.

In some embodiments, when viewed along the direction perpendicular to the first surface, the substrate may have a rectangular shape having a long side and a short side, and the at least one groove may extend along the long side of the substrate.

The description of the foregoing embodiments may be referred to for the detail of the groove, which will not be repeatedly described herein for the sake of conciseness.

In step 702, injection molding may be performed on the packaged chip to form a bottom filling layer filling the gap between the chip and the first surface of the substrate, and a plastic packaging layer covering the bottom filling layer and packaging the chip.

Because the gap between the substrate and the chip is relatively small, the capillary effect may be used. After providing a bottom filler at the edges of the substrate, the capillary effect may be used to cause the bottom filler to automatically fill in the gap between the chip and the substrate. In the filling process, the gas between the chip and the substrate may be removed from the edges of the substrate through the groove in the first surface of the substrate.

In some embodiments, performing injection molding on the packaged chip may include: providing an injection mold, the injection mold including an under-pan and a cover configured to cover the under-pan to form a cavity with the under-pan; placing the packaged chip in the cavity, the substrate being placed on the surface of the under-pan; filling, using the capillary effect, the bottom filler in the gap between the bottom of the chip and the substrate; injecting a liquid-state plastic packaging material into the cavity until the cavity is filled with the liquid-state plastic packaging material; and performing heating to solidify the liquid-state plastic packaging material and the bottom filler, to form the solid-state plastic packaging layer and bottom filling layer. The bottom filling layer and the plastic packaging layer may be made of the same injection molding material or different injection molding material, and this specification is not limited in this regard.

The cover may include at least one hole connecting the cavity to the outside. And the method may further include: injecting the liquid-state plastic packaging material into the cavity through the at least one hole.

In some embodiments, the cover may include a separable side wall and top cover. The at least one hole may be disposed in the side wall. The bottom filler and the liquid-state plastic packaging material may be injected into the cavity through the hole. The bottom filler may first be slowly injected into the cavity through the hole. After reaching the substrate, the bottom filler may be filled between the chip and the substrate by using the capillary effect. Then, the liquid-state plastic packaging material may be injected to fill the entire cavity.

In some embodiments, the cover may include at least two holes. And the method may further include removing the gas inside the cavity through at least one of the holes in the injection molding process. The hole configured to remove gas may be disposed in the side wall or the top cover of the cover.

In the injection molding process, because the width of the groove is smaller than the fillable width of the bottom filler in the liquid state, the liquid-state plastic packaging material can seal the top of the groove, without filling the groove, to form a continuous gas path inside the groove. And the groove may effectively remove gas in the injection molding process.

In the foregoing embodiments, after placing the packaged chip into the packaging mold, the filling layer may be formed by using the capillary effect. Then the plastic packaging layer may be formed by using the plastic packaging material to fill the cavity.

In some other embodiments, before placing the packaged chip into the packaging mold, the filling layer may be first formed between the chip and the substrate by using the capillary effect. Then the packaged chip may be placed into the packaging mold to form the plastic packaging layer packaging the upper portion of the chip.

In step 703, solder balls may be formed on the second surface of the substrate after taking the injection-molded packaged chip from the cavity. The solder balls may be distributed on the entire second surface of the substrate.

The solder balls may be lead solder balls, lead-free solder balls, and this specification is not limited in this regard. Subsequently, the packaged structure may be mounted onto other electronic components such as a circuit board by using the solder balls 203 through a reflow soldering process.

In the embodiments of the present invention, a plurality of chips may be formed on the surface of the substrate, and plastic packaging may be performed on the plurality of chips and the substrate. After the plastic packaging is completed, structures such as solder balls may be further formed on the second surface of the substrate and the packaged structure shown in FIG. 3A may be formed by cutting.

According to the forming method of the packaged structure, in the injection molding process, the gas inside the packaged structure may be removed through the groove having the ends in the substrate and open to the exterior. Because the depth of the groove is smaller than the depth of the substrate, the second surface of the substrate is not adversely affected by the groove, and the area used to form the solder balls on the second surface is not be occupied.

Further, because the width of the groove is relatively small, the bottom filler in the injection molding process does not fill the groove, thereby preventing the groove from being blocked and improving the gas removal efficiency of the groove.

The foregoing descriptions are some embodiments of the present invention. A person of ordinary skills in the art may further make various improvements or modifications without departing from the principle of the present invention. Such improvements or modifications shall also fall within the protection scope of the present invention.

What is claimed is:

1. A packaged structure, comprising:
a substrate having a first surface and a second surface opposite to each other, the first surface having at least one strip-shaped groove having two ends extending to edges of the substrate and open to the exterior, a depth of the groove being smaller than a thickness of the substrate;
a chip fastened onto the first surface of the substrate in a flipping manner by using solder bumps and electrically connected to the substrate through the solder bumps, at least a portion of the groove located within a projection of the chip on the substrate when viewed along a direction perpendicular to the first surface;
a bottom filling layer filling a gap between the chip and the first surface of the substrate; and
a plastic packaging layer, covering the bottom filling layer and packaging the chip.

2. The packaged structure of claim 1, wherein the first surface of the substrate comprises at least two grooves arranged parallelly or crossly.

3. The packaged structure of claim 1, wherein a width of the groove is smaller than a fillable width of a material of the bottom filling layer in a liquid state.

4. The packaged structure of claim 1, wherein the width of the groove is smaller than 4 μm.

5. The packaged structure of claim 1, wherein the depth of the groove is in a range of 1% to 70% of the thickness of the substrate.

6. The packaged structure of claim 1, wherein the depth of the groove is 80 μm to 0.5 mm.

7. The packaged structure of claim 1, wherein the groove is straight or curved.

8. The packaged structure of claim 1, wherein the at least one groove is located at a position of a symmetry axis of the substrate.

9. The packaged structure of claim 1, wherein viewing along a direction perpendicular to the first surface, the substrate has a rectangular shape having a long side and a short side, and the at least one groove extends along the long side of the substrate.

10. The packaged structure of claim 1, wherein a top of the groove is sealed by the bottom filling layer, and the groove has a continuous gas path is formed inside the groove.

11. The packaged structure of claim 1, further comprising: solder balls, formed on the second surface of the substrate.

12. A forming method of a packaged structure, comprising:
providing a packaged chip, wherein the packaged chip comprises a substrate and a chip, the substrate has a first surface and a second surface opposite to each other, the first surface having at least one strip-shaped groove having two ends extending to edges of the substrate and open to the exterior, a depth of the groove being smaller than a thickness of the substrate,
wherein the chip is fastened onto the first surface of the substrate in a flipping manner by using solder bumps, the solder bumps are electrically connected to the substrate, and at least a portion of the groove is located within a projection of the chip on the substrate when viewed along a direction perpendicular to the first surface; and
performing injection molding on the packaged chip to form a bottom filling layer filling a gap between the chip and the first surface of the substrate, and a plastic packaging layer covering the bottom filling layer and packaging the chip.

13. The forming method of claim 12, wherein gas inside the packaged structure is removed through the groove in a process of forming the bottom filling layer.

14. The forming method of claim 12, wherein performing injection molding on the packaged chip comprises:
providing an injection mold, wherein the injection mold comprises an under-pan and a cover, and the cover is configured to cover the under-pan to form a cavity with the under-pan;
placing the packaged chip in the cavity, wherein the substrate is placed on the surface of the under-pan;
filling, using a capillary effect, a bottom filler in the gap between the bottom of the chip and the substrate;
injecting a liquid-state plastic packaging material into the cavity until the cavity is filled with the liquid-state plastic packaging material; and
performing heating to solidify the liquid-state plastic packaging material and the bottom filler, to form a solid-state plastic packaging layer and bottom filling layer.

15. The forming method of claim 14, wherein the cover comprises at least one hole connecting the cavity to outside, and the method further comprises:
injecting, through the at least one hole, the liquid-state plastic packaging material into the cavity.

16. The forming method of claim 15, wherein the cover comprises at least two holes, and the method further comprises:
removing gas inside the cavity through at least one of the holes in an injection molding process.

17. The forming method of claim 12, wherein in the injection molding process, the bottom filler seals a top of the groove without filling the groove to form a continuous gas path inside the groove.

18. The forming method of claim 12, further comprising:
forming solder balls on the second surface of the substrate.
